(19) United States
(12) Patent Application Publication
(10) Pub. No.: US 2025/0246449 A1
(43) Pub. Date: Jul. 31, 2025

(54) LIQUID SUPPLY SYSTEM, LIQUID PROCESSING APPARATUS, AND LIQUID SUPPLY METHOD

(71) Applicant: Tokyo Electron Limited, Tokyo (JP)

(72) Inventors: So OSADA, Kumamoto (JP); Kazuki KOSAI, Kumamoto (JP); Kazuyoshi SHINOHARA, Kumamoto (JP); Katsuya OKUDA, Kumamoto (JP); Toshiyuki SHIOKAWA, Kumamoto (JP)

(21) Appl. No.: 18/855,140

(22) PCT Filed: Apr. 7, 2023
(86) PCT No.: PCT/JP2023/014327

§ 371 Date: Oct. 8, 2024

(30) Foreign Application Priority Data
Apr. 21, 2022 (JP) 2022-069916
Jan. 12, 2023 (JP) 2023-003169

(51) Int. Cl. H01L 21/67; G05D 16/20

(52) U.S. Cl. CPC H01L 21/67017; G05D 16/208

(57) ABSTRACT

A liquid supply system includes: a tank that stores a processing liquid; a circulation line that returns the processing liquid sent from the tank, to the tank; a pump that forms a circulation flow of the processing liquid in the circulation line; a filter provided on a downstream side of the pump in the circulation line; a back pressure valve provided on a downstream side of the filter in the circulation line; and a controller that controls each unit. When stopping an operation of the pump, the controller controls the pump and the back pressure valve such that a differential pressure between an upstream side and a downstream side of the filter becomes equal to or less than a predetermined threshold value, during a period from when a discharge pressure of the pump starts to decrease until the operation of the pump is stopped.

### TECHNICAL FIELD

An embodiment of the present disclosure relates to a liquid supply system, a liquid processing apparatus, and a liquid supply method.

### BACKGROUND

Conventionally, there has been known a liquid processing apparatus that circulates a processing liquid for substrates such as a semiconductor wafer (hereinafter, also referred to as a wafer) through a circulation line, and supplies the processing liquid to a processing section through a branch line diverging from the circulation line. The circulation line of such a liquid processing apparatus is provided with a filter that removes foreign matter from the processing liquid (see Patent Document 1).

### PRIOR ART DOCUMENT

### Patent Document

### Patent Document 1: Japanese Patent Laid-open Publication No. 2019-41039

### SUMMARY OF THE INVENTION

### Problem to be Solved

The present disclosure provides a technique capable of suppressing contamination of a processing liquid within a circulation line.

### Means to Solve the Problem

A liquid supply system according to an aspect of the present disclosure includes a tank, a circulation line, a pump, a filter, a back pressure valve, and a controller. The tank stores the processing liquid. The circulation line returns the processing liquid sent from the tank, to the tank. The pump forms the circulation flow of the processing liquid in the circulation line. The filter is provided on the downstream side of the pump in the circulation line. The back pressure valve is provided on the downstream side of the filter in the circulation line. The controller controls each unit. Also, when stopping the operation of the pump, the controller controls the pump and the back pressure valve such that the differential pressure between the upstream side and the downstream side of the filter may be equal to or less than a predetermined threshold value, during a period from when the discharge pressure of the pump starts to decrease until the operation of the pump is stopped.

### Effect of the Invention

According to the present disclosure, it is possible to suppress contamination of a processing liquid within a circulation line. Also, the effects described herein are not necessarily limiting, and may be any one of the effects described in the present disclosure.

### BRIEF DESCRIPTION OF THE DRAWINGS

FIG. 1 is a schematic view illustrating a schematic configuration of a substrate processing system according to an embodiment.

FIG. 2 is a schematic view illustrating the configuration of a processing unit according to the embodiment.

FIG. 3 is a view illustrating a schematic configuration of a processing liquid supply source according to the embodiment.

FIG. 4 is a view illustrating the transition of the differential pressure between the upstream side and the downstream side of a filter, in a reference example.

FIG. 5 is a view illustrating the transition of the differential pressure between the upstream side and the downstream side of a filter according to the embodiment.

FIG. 6 is a view illustrating a schematic configuration of a processing liquid supply source according to a first modification of the embodiment.

FIG. 7 is a view illustrating the transition of the flow rate of a processing liquid in a circulation line according to the first modification of the embodiment.

FIG. 8 is a view illustrating a schematic configuration of a processing liquid supply source according to a second modification of the embodiment.

FIG. 9 is a view illustrating the procedure of a start-up process in the processing liquid supply source according to the second modification of the embodiment.

FIG. 10 is a view illustrating the procedure of the start-up process in the processing liquid supply source according to the second modification of the embodiment.

FIG. 11 is a view illustrating the procedure of the start-up process in the processing liquid supply source according to the second modification of the embodiment.

FIG. 12 is a view illustrating a schematic configuration of a processing liquid supply source according to a third modification of the embodiment.

FIG. 13 is a view illustrating the procedure of a start-up process in the processing liquid supply source according to the third modification of the embodiment.

FIG. 14 is a view illustrating the procedure of the start-up process in the processing liquid supply source according to the third modification of the embodiment.

FIG. 15 is a view illustrating the procedure of the start-up process in the processing liquid supply source according to the third modification of the embodiment.

FIG. 16 is a view illustrating a schematic configuration of a processing liquid supply source according to a fourth modification of the embodiment.

FIG. 17 is a flowchart illustrating an example of the procedure of the control process executed by the substrate processing system according to the embodiment.

### DETAILED DESCRIPTION TO EXECUTE THE INVENTION

Hereinafter, embodiments of a liquid supply system, a liquid processing apparatus and a liquid supply method according to the disclosure of the present application will be described in detail with reference to accompanying drawings. Also, the present disclosure is not limited by the embodiments to be described below. Also, it should be noted that the drawings are schematic, and the dimensional relationship between individual elements, and the ratio of each element may be different from actual ones in some cases. Furthermore, in some cases, in the drawings, parts whose dimensional relationships or ratios are different from each other may be included.

Conventionally, there has been known a liquid processing apparatus, in which a processing liquid for a substrate such as a semiconductor wafer (hereinafter, also referred to as a wafer) is circulated through a circulation line, and the processing liquid is supplied to a processing unit through a branch line diverging from such a circulation line. The circulation line of the liquid processing apparatus is provided with a filter that removes foreign matter from the processing liquid.

However, in a conventional circulation line, when the circulation flow of the processing liquid is shut down for maintenance, etc., there is a risk that foreign matter may pass through the filter due to the discharge pressure of a pump, thereby contaminating the processing liquid in the circulation line.

Therefore, there is an expectation that a technology capable of suppressing contamination of the processing liquid in the circulation line by overcoming the above-described problems may be implemented.

### <Outline of Substrate Processing System>

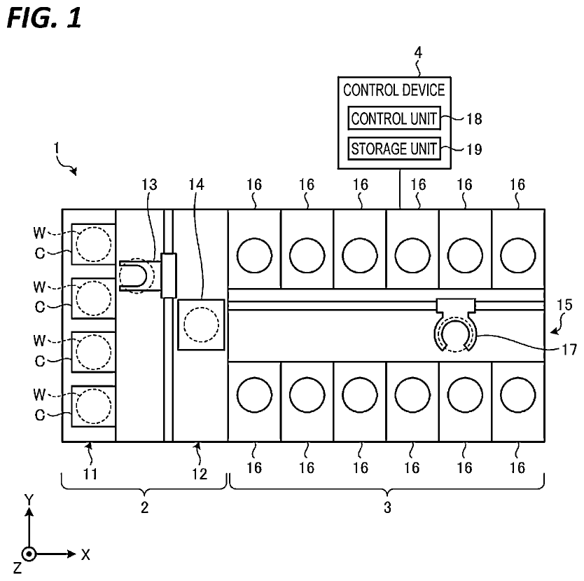

First, descriptions will be made on a schematic configuration of a substrate processing system 1 according to an embodiment, with reference to FIG. 1. FIG. 1 is a view illustrating a schematic configuration of the substrate processing system 1 according to the embodiment. The substrate processing system 1 is an example of a liquid processing apparatus. Hereinafter, in order to clarify the positional relationship, an X-axis, a Y-axis and a Z-axis which are orthogonal to each other are defined, and the positive direction of the Z axis is set as a vertical upward direction.

As illustrated in FIG. 1, the substrate processing system 1 includes a loading/unloading station 2, and a processing station 3. The loading/unloading station 2 and the processing station 3 are provided adjacent to each other.

The loading/unloading station 2 includes a carrier placement section 11, and a transport section 12. In the carrier placement section 11, a plurality of carriers C accommodating a plurality of substrates, semiconductor wafers W in the embodiment (hereinafter, referred to as wafers W) in a horizontal state is placed.

The transport section 12 is provided adjacent to the carrier placement section 11, and includes, therein, a substrate conveyance device 13, and a transfer unit 14. The substrate conveyance device 13 includes a wafer holding mechanism that holds wafers W. Also, the substrate conveyance device 13 is capable of moving in the horizontal direction and the vertical direction and rotating around the vertical axis, and transfers the wafers W to/from the carriers C/the transfer unit 14 by using the wafer holding mechanism.

The processing station 3 is provided adjacent to the transport section 12. The processing station 3 includes a transport section 15, and a plurality of processing units 16. The processing units 16 are provided side by side on both sides of the transport section 15.

The transport section 15 includes, therein, a substrate conveyance device 17. The substrate conveyance device 17 includes a wafer holding mechanism that holds wafers W. Also, the substrate conveyance device 17 is capable of moving in the horizontal direction and the vertical direction and rotating around the vertical axis, and transfers the wafers W from/to the transfer unit 14/the processing unit 16 by using the wafer holding mechanism.

The processing unit 16 is an example of a liquid processing unit, and performs predetermined substrate processing on the wafer W conveyed by the substrate conveyance device 17.

Also, the substrate processing system 1 includes a control device 4. The control device 4 is, for example, a computer, and includes a control unit 18 and a storage unit 19. The storage unit 19 stores programs that control various processes to be executed in the substrate processing system 1. The control unit 18 controls the operation of the substrate processing system 1 by reading and executing the program stored in the storage unit 19.

Also, these programs may be recorded in a computer-readable storage medium, and may be installed to the storage unit 19 of the control device 4 from the storage medium. Examples of the computer-readable storage medium include hard disks (HD), flexible disks (FD), compact discs (CD), magnetic optical discs (MO), and memory cards.

In the substrate processing system 1 configured as described above, first, the substrate conveyance device 13 of the loading/unloading station 2 takes out a wafer W from the carrier C placed on the carrier placement section 11, and places the extracted wafer W on the transfer unit 14. The wafer W placed on the transfer unit 14 is taken out of the transfer unit 14 by the substrate conveyance device 17 of the processing station 3 and is carried into the processing unit 16.

The wafer W carried into the processing unit 16 is processed by the processing unit 16, and then is carried out of the processing unit 16 by the substrate conveyance device 17 and is placed on the transfer unit 14. Then, the processed wafer W placed on the transfer unit 14 is returned to the carrier C of the carrier placement section 11 by the substrate conveyance device 13.

### <Outline of Processing Unit>

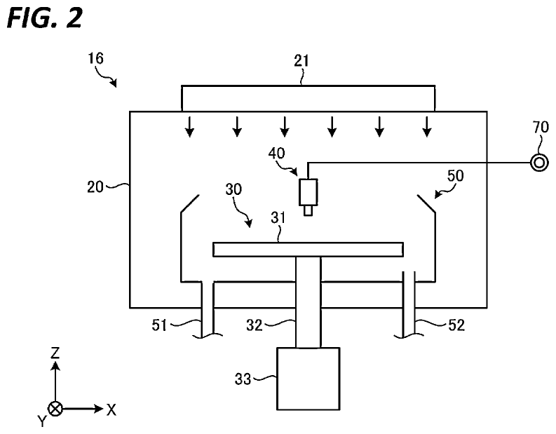

Next, the outline of the processing unit 16 will be described with reference to FIG. 2. FIG. 2 is a schematic view illustrating the configuration of the processing unit 16 according to the embodiment. The processing unit 16 includes a chamber 20, a substrate processing section 30, a liquid supply 40, and a recovery cup 50.

The chamber 20 accommodates the substrate processing section 30, the liquid supply 40, and the recovery cup 50. A fan filter unit (FFU) 21 is provided in the ceiling of the chamber 20. The FFU 21 forms a downflow within the chamber 20.

The substrate processing section 30 includes a holder 31, a support 32, and a driving unit 33, and performs liquid processing on the placed wafer W. The holder 31 horizontally holds the wafer W (see FIG. 1). The support 32 is a member extending in the vertical direction, in which the base end is rotatably supported by the driving unit 33, and the distal end horizontally supports the holder 31. The driving unit 33 rotates the support 32 around the vertical axis.

The substrate processing section 30 rotates the support 32 by using the driving unit 33 so that the holder 31 supported by the support 32 is rotated. Accordingly, the wafer W held by the holder 31 is rotated.

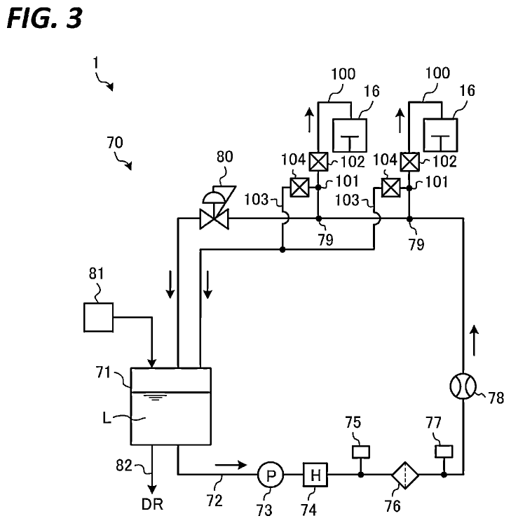

The liquid supply 40 supplies a processing liquid L to the wafer W (see FIG. 3). The liquid supply 40 is connected to a processing liquid supply source 70. The liquid supply 40 includes a plurality of nozzles. Such a plurality of nozzles is provided corresponding to, for example, a plurality of types of processing liquids L. Also, the nozzles eject the multiple types of processing liquids L supplied from the processing liquid supply sources 70, respectively, to the wafer W.

The recovery cup 50 is disposed to surround the holder 31, and collects the processing liquid L scattering from the wafer W due to rotation of the holder 31. A drainage port 51 is formed at the bottom of the recovery cup 50, and the processing liquid L collected by the recovery cup 50 is discharged from this drainage port 51 to the outside of the processing unit 16.

Also, an exhaust port 52 is formed at the bottom of the recovery cup 50 so as to discharge the gas supplied from the FFU 21, to the outside of the processing unit 16.

### <Outline of Processing Liquid Supply Source>

Next, a schematic configuration of the processing liquid supply source 70 provided in the substrate processing system 1 will be described with reference to FIG. 3. FIG. 3 is a view illustrating a schematic configuration of the processing liquid supply source 70 according to the embodiment. The processing liquid supply source 70 is an example of a liquid supply system.

As illustrated in FIG. 3, the processing liquid supply source 70 included in the substrate processing system 1 supplies the processing liquid L to the plurality of processing units 16. Also, in the embodiment, for example, the processing liquid supply source 70 illustrated in FIG. 3 is provided for each of the multiple types of processing liquids L.

As illustrated in FIG. 3, the processing liquid supply source 70 includes a tank 71, a circulation line 72, a pump 73, a heater 74, a first pressure sensor 75, a filter 76, a second pressure sensor 77, a flowmeter 78, a plurality of junctions 79, and a back pressure valve 80.

The tank 71 stores the processing liquid L. The processing liquid L is, for example, isopropyl alcohol (IPA) . . . . Also, the processing liquid L of the present disclosure is not limited to IPA, and various types of chemical liquids can be applied.

Through the circulation line 72, the processing liquid L sent from the tank 71 is returned to the tank 71. In this circulation line 72, the pump 73, the heater 74, the first pressure sensor 75, the filter 76, the second pressure sensor 77, the flowmeter 78, the plurality of junctions 79, and the back pressure valve 80 are provided in this order from the upstream side with respect to the tank 71.

The pump 73 forms a circulation flow of the processing liquid L in the circulation line 72. Also, in the embodiment, the discharge pressure of the pump 73 can be controlled by the control unit 18 (see FIG. 1).

The heater 74 is an example of a heating mechanism, and heats the processing liquid L circulating through the circulation line 72. The control unit 18 may adjust the temperature of the processing liquid L by controlling the heating amount of the processing liquid L in the heater 74.

For example, the amount of the processing liquid L to be heated by the heater 74 is adjusted on the basis of the temperature of the processing liquid L. The temperature is detected by a temperature sensor (not illustrated) provided in the tank 71 and the circulation line 72.

The first pressure sensor 75 measures the pressure of the processing liquid L on the upstream side of the filter 76. The filter 76 removes contaminants such as particles contained in the processing liquid L circulating through the inside of the circulation line 72.

The second pressure sensor 77 measures the pressure of the processing liquid L on the downstream side of the filter 76. The flowmeter 78 measures the flow rate of the circulation flow of the processing liquid L formed in the circulation line 72. Supply lines 100 diverge from the junctions 79 and are connected to the nozzles of the processing units 16, respectively.

This supply line 100 is provided with a junction 101 and a valve 102 in this order from the upstream side. A return line 103 diverges from the junction 101 and is connected to the tank 71. A valve 104 is provided in this return line 103.

The valves 102 and 104 control supplying or non-supplying of the processing liquid L from the supply line 100 to the processing unit 16. The control unit 18 supplies the processing liquid L from the supply line 100 to the processing unit 16 by opening the valve 102 and closing the valve 104.

Meanwhile, the control unit 18 closes the valve 102 and opens the valve 104 so as not to supply the processing liquid L from the supply line 100 to the processing unit 16. In this case, the processing liquid L in the supply line 100 returns to the tank 71 through the return line 103.

The back pressure valve 80 increases a valve opening degree when the pressure of the processing liquid L on the upstream side of the back pressure valve 80 is greater than a desired pressure. Meanwhile, the back pressure valve 80 decreases the valve opening degree when the pressure of the processing liquid L on the upstream side of the back pressure valve 80 is less than a desired pressure.

Accordingly, the back pressure valve 80 has a function of maintaining the pressure of the processing liquid L on the upstream side, at a desired pressure. Also, in the embodiment, the valve opening degree of the back pressure valve 80 can be controlled by the control unit 18.

Also, the tank 71 has a processing liquid replenishing unit 81, and a drain line 82. The processing liquid replenishing unit 81 replenishes the tank 71 with the processing liquid L. The drain line 82 discharges the processing liquid L in the tank 71, to a drain section DR, for example, when the processing liquid L in the tank 71 is replaced.

In the processing liquid supply source 70 described so far, the pressures at the plurality of junctions 79 are maintained at a desired pressure by the back pressure valve 80, so that the processing liquid L may be smoothly supplied from the processing liquid supply source 70 to each of the processing units 16.

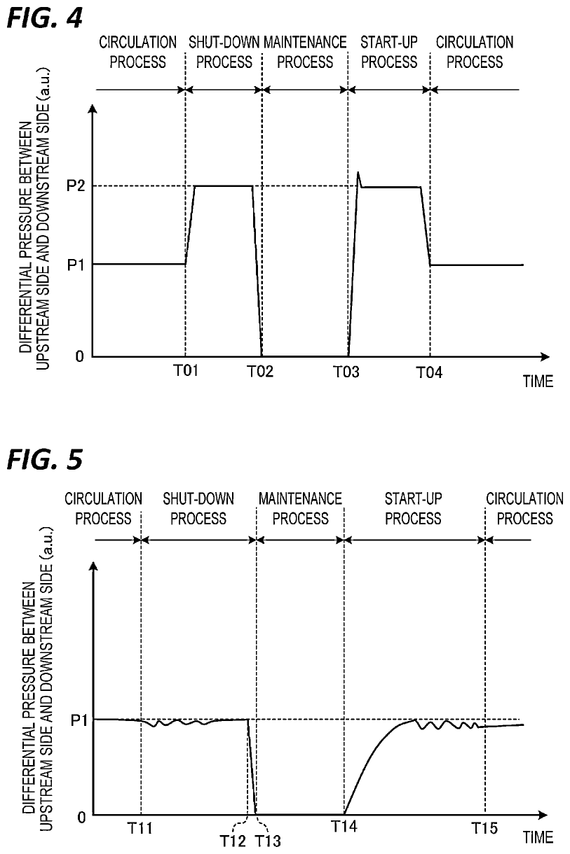

Meanwhile, in some cases, immediately before, for example, the replacement work of the processing liquid L or the recovery work from trouble, when the circulation flow of the processing liquid L is shut down in the circulation line 72, foreign matter may pass through the filter 76 due to the discharge pressure of the pump 73, thereby contaminating the processing liquid L in the circulation line 72. The details of this problem will be described with reference to FIG. 4.

FIG. 4 is a view illustrating the transition of the differential pressure between the upstream side and the downstream side of the filter 76, in a reference example. As illustrated in FIG. 4, until time T01 when a shut-down process of the circulation flow starts, the control unit 18 performs a circulation process of forming the circulation flow of the processing liquid L in the circulation line 72.

In this circulation process, since the pump 73 is operated at the rated output of the pump 73, the discharge pressure of the pump 73 (i.e., the pressure on the upstream side of the filter 76) is substantially constant. Also, in this circulation process, since the back pressure valve 80 is operated so as to keep the pressure on the upstream side of the back pressure valve 80 constant, the pressure on the downstream side of the filter 76 is also substantially constant.

That is, in this reference example, the differential pressure between the upstream side and the downstream side of the filter 76 becomes a substantially constant differential pressure P1. Also, this differential pressure P1 becomes a value smaller than the rated discharge pressure of the pump 73.

Next, at time T01, when the shut-down process of shutting down the circulation flow of the processing liquid L in the circulation line 72 starts, first, the control unit 18 turns OFF the control of the back pressure valve 80. This is because there is a contact risk in the back pressure valve 80 when the circulation flow in the circulation line 72 is stopped while the back pressure valve 80 is turned ON.

Then, the valve opening degree of the back pressure valve 80 is fully opened, and thus, the pressure on the upstream side of the back pressure valve 80 [i.e., the downstream side of the filter 76] suddenly drops. Therefore, the differential pressure between the upstream side and the downstream side of the filter 76 suddenly rises, and such a large differential pressure P2 that may exceed the differential-pressure resistance of the filter 76 is applied to the filter 76.

Therefore, in the reference example, in some cases, due to this large differential pressure P2, foreign matter trapped in the filter 76 may pass through the filter 76 during the shut-down process.

Next, when the control unit 18 shuts down the pump 73 after turning OFF the control of the back pressure valve 80, the discharge pressure of the pump 73 gradually decreases. At time T02, the discharge pressure becomes zero. Accordingly, the pressure on the upstream side of the filter 76 becomes zero, and thus, the differential pressure between the upstream side and the downstream side of the filter 76 also becomes zero. Then, the shut-down process of the circulation flow is ended. Next, the user performs a maintenance process for, for example, the processing liquid supply source 70.

After this maintenance process is ended, in order to start up the circulation flow of the processing liquid L in the circulation line 72, the control unit 18 starts up the pump 73 at time T03 and turns ON the control of the back pressure valve 80 (a start-up process).

However, since there is a given time lag until the control of the back pressure valve 80 is stably operated, the back pressure valve 80 is not sufficiently controlled until the control is stabilized.

Accordingly, as illustrated in FIG. 4, the large differential pressure P2 that may exceed the differential-pressure resistance of the filter 76 is applied between the upstream side and the downstream side of the filter 76, from time T03 when the pump 73 starts to operate to time T04 when the control of the back pressure valve 80 starts to function sufficiently.

Therefore, in the reference example, in some cases, due to such a large differential pressure P2, foreign matter trapped in the filter 76 may pass through the filter 76 during the start-up process. Also, from time T04 when the control of the back pressure valve 80 is fully operated, the circulation process is started again.

As described above, in the reference example, in some cases, when the shut-down process and the start-up process are carried out before and after the maintenance process, foreign matter may pass through the filter 76 due to the discharge pressure of the pump 73, thereby contaminating the processing liquid L in the circulation line 72.

Therefore, in the embodiment, a control process to be described below is carried out so as to suppress the contamination of the processing liquid L in the circulation line 72. FIG. 5 is a view illustrating the transition of the differential pressure between the upstream side and the downstream side of the filter 76 according to the embodiment.

As illustrated in FIG. 5, until time T11 when a shut-down process of the pump 73 starts, the control unit 18 performs the circulation process of forming a circulation flow of the processing liquid L in the circulation line 72. In this circulation process, as in the above-described reference example, the differential pressure between the upstream side and the downstream side of the filter 76 becomes a substantially constant differential pressure P1.

Next, at time T11, when the shut-down process of shutting down the circulation flow of the processing liquid L in the circulation line 72 starts, the control unit 18 gradually lowers the discharge pressure of the pump 73 while the control of the back pressure valve 80 is still turned ON.

Furthermore, the control unit 18 controls the pump 73 and the back pressure valve 80 such that the differential pressure between the upstream side and the downstream side of the filter 76 is equal to or less than a predetermined threshold value (e.g., the differential pressure P1 during circulation).

In such a control, the differential pressure between the upstream side and the downstream side of the filter 76 is obtained by measuring the pressure on the upstream side of the filter 76 by the first pressure sensor 75, and measuring the pressure on the downstream side of the filter 76 by the second pressure sensor 77.

Also, for example, the control unit 18 controls the differential pressure between the upstream side and the downstream side of the filter 76 to be equal to or less than the differential pressure P1 by lowering the discharge pressure of the pump 73 and increasing the valve opening degree of the back pressure valve 80.

In the embodiment, this control process can suppress the filter 76 from being subjected to a large differential pressure that may exceed the differential-pressure resistance during the shut-down process. Thus, it is possible to suppress foreign matter trapped in the filter 76 from passing through the filter 76.

Therefore, according to the embodiment, contamination of the processing liquid L in the circulation line 72 can be suppressed.

Also, in the embodiment, by lowering the discharge pressure of the pump 73 and increasing the valve opening degree of the back pressure valve 80, the differential pressure between the upstream side and the downstream side of the filter 76 may be controlled to be equal to or less than the differential pressure P1.

This makes it possible to smoothly suppress the filter 76 from being subjected to a large differential pressure that may exceed the differential-pressure resistance. Therefore, according to the embodiment, contamination of the processing liquid L in the circulation line 72 may be further suppressed.

Also, in the embodiment, the control unit 18 constantly monitors the first pressure sensor 75 and the second pressure sensor 77 in the circulation process prior to the shut-down process, and calculates in advance the maximum differential pressure between the first pressure sensor 75 and the second pressure sensor 77 in the circulation process.

Then, during the shut-down process, the control unit 18 may control the pump 73 and the back pressure valve 80 such that the differential pressure between the upstream side and the downstream side of the filter 76 may be equal to or less than the maximum differential pressure between the first pressure sensor 75 and the second pressure sensor 77 during the circulation process.

Accordingly, during the shut-down process, it is possible to suppress the application of a differential pressure larger than the differential pressure applied to the filter 76 during the most recent circulation process. Thus, foreign matter trapped in the filter 76 may be further suppressed from passing through the filter 76.

Therefore, according to the embodiment, contamination of the processing liquid L in the circulation line 72 may be further suppressed.

Also, in the example of FIG. 5, descriptions have been made on an example in which in the shut-down process, the differential pressure between the upstream side and the downstream side of the filter 76 is controlled to be equal to or less than the differential pressure P1 in the circulation process, but the present disclosure is not limited to such an example.

For example, in the present disclosure, in the shut-down process, the pump 73 and the back pressure valve 80 may be controlled such that the differential pressure between the upstream side and the downstream side of the filter 76 may be equal to or less than a pressure slightly higher than the differential pressure P1 in the circulation process.

This also makes it possible to suppress the filter 76 from being subjected to a large differential pressure that may exceed the differential-pressure resistance during the shut-down process. Therefore, foreign matter trapped in the filter 76 may be suppressed from passing through the filter 76.

Therefore, according to the embodiment, contamination of the processing liquid L in the circulation line 72 may be suppressed.

FIG. 5 will be continuously described. As described above, the control unit 18 controls the differential pressure between the upstream side and the downstream side of the filter 76 to be equal to or less than the differential pressure P1 by lowering the discharge pressure of the pump 73 and increasing the valve opening degree of the back pressure valve 80.

Then, when the valve opening degree of the back pressure valve 80 is fully opened, and the differential pressure between the upstream side and the downstream side of the filter 76 is equal to or less than the differential pressure P1 (time T12), the control unit 18 assumes that the discharge pressure of the pump 73 is equal to or less than the differential pressure P1, and turns OFF the control of the back pressure valve 80.

Then, when the control unit 18 shuts down the pump 73 after turning OFF the control of the back pressure valve 80, the discharge pressure of the pump 73 decreases. At time T13, the discharge pressure becomes zero. Next, the user performs a maintenance process for, for example, the processing liquid supply source 70.

Then, after this maintenance process is ended, in order to start up the circulation flow of the processing liquid L in the circulation line 72, the control unit 18 starts up the pump 73 at time T14 and turns ON the control of the back pressure valve 80 (a start-up process).

Here, in the embodiment, in order to prevent an excessive increase in the differential pressure between the upstream side and the downstream side of the filter 76 until the back pressure valve 80 is sufficiently operated, the control unit 18 operates the pump 73 such that the discharge pressure of the pump 73 may gradually increase.

Accordingly, as illustrated in FIG. 5, it is possible to suppress the filter 76 from being subjected to a large differential pressure that may exceed the differential-pressure resistance during the start-up process. Therefore, foreign matter trapped in the filter 76 may be suppressed from passing through the filter 76.

Therefore, according to the embodiment, contamination of the processing liquid L in the circulation line 72 may be suppressed.

Also, in the embodiment, in the start-up process, the pump 73 and the back pressure valve 80 may be controlled such that the differential pressure between the upstream side and the downstream side of the filter 76 may be equal to or less than the maximum differential pressure between the first pressure sensor 75 and the second pressure sensor 77 in the above-described previous circulation process.

Accordingly, in the start-up process, it is possible to suppress the application of a differential pressure larger than the differential pressure applied to the filter 76 in the most recent circulation process. Thus, foreign matter trapped in the filter 76 may be further suppressed from passing through the filter 76.

Therefore, according to the embodiment, contamination of the processing liquid L in the circulation line 72 may be further suppressed. Also, in the embodiment, the circulation process is started again from time T15 when the control of the back pressure valve 80 is fully operated.

### First Modification

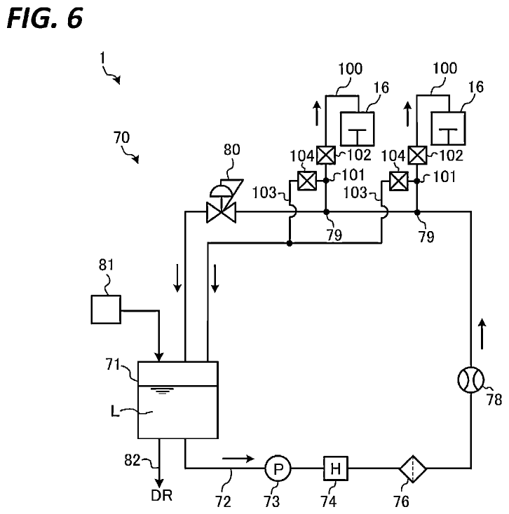

Next, various modifications of the substrate processing system 1 according to the embodiment will be described with reference to FIG. 6 to FIG. 16. FIG. 6 is a view illustrating a schematic configuration of the processing liquid supply source 70 according to a first modification of the embodiment.

As illustrated in FIG. 6, this first modification is different from the above-described embodiment in that the first pressure sensor 75 and the second pressure sensor 77 are not provided in the circulation line 72. Therefore, in the following example, the same parts as those in the already-described embodiment are denoted by the same reference numerals, and detailed descriptions thereof will be omitted.

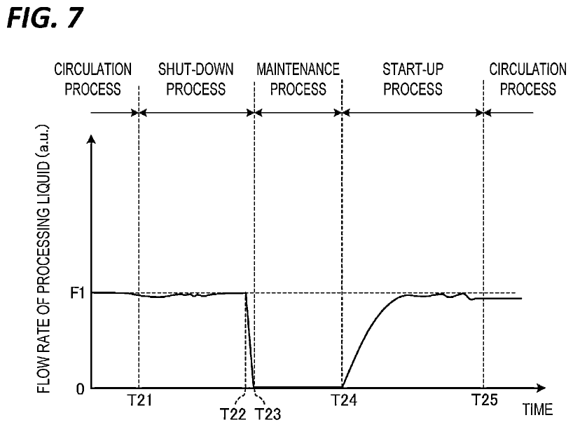

Then, in the first modification, a control process to be described below is carried out so as to suppress the contamination of the processing liquid L in the circulation line 72. FIG. 7 is a view illustrating the transition of the flow rate of the processing liquid L in the circulation line 72 according to the first modification of the embodiment.

As illustrated in FIG. 7, until time T21 when a shut-down process of the pump 73 starts, the control unit 18 performs the circulation process of forming a circulation flow of the processing liquid L in the circulation line 72. In this circulation process, the flow rate of the processing liquid L in the circulation line 72 becomes a substantially constant flow rate F1.

Next, at time T21, when the shut-down process of shutting down the circulation flow of the processing liquid L in the circulation line 72 starts, the control unit 18 gradually lowers the discharge pressure of the pump 73 while the control of the back pressure valve 80 is still turned ON.

Furthermore, the control unit 18 controls the pump 73 and the back pressure valve 80 such that the flow rate of the processing liquid L in the circulation line 72 is equal to or less than a predetermined threshold value (e.g., the flow rate F1 during circulation). In such a control, the flow rate of the processing liquid L in the circulation line 72 can be measured by the flowmeter 78.

Also, for example, the control unit 18 controls the flow rate of the processing liquid L in the circulation line 72 to be equal to or less than the flow rate F1 by lowering the discharge pressure of the pump 73 and increasing the valve opening degree of the back pressure valve 80.

In the first modification, this control process can suppress the flowing of the processing liquid at a large flow rate through the filter 76 during the shut-down process. Thus, it is possible to suppress foreign matter trapped in the filter 76 from passing through the filter 76.

Therefore, according to the first modification, contamination of the processing liquid L in the circulation line 72 can be suppressed.

Also, in the first modification, by lowering the discharge pressure of the pump 73 and increasing the valve opening degree of the back pressure valve 80, the flow rate of the processing liquid L in the circulation line 72 may be controlled to be equal to or less than the flow rate F1.

This makes it possible to smoothly suppress the flowing of the processing liquid at a large flow rate through the filter 76. Therefore, according to the first modification, contamination of the processing liquid L in the circulation line 72 may be further suppressed.

Also, in the first modification, the control unit 18 constantly monitors the flowmeter 78 in the circulation process prior to the shut-down process, and calculates in advance the maximum flow rate of the processing liquid L in the circulation process.

Then, during the shut-down process, the control unit 18 may control the pump 73 and the back pressure valve 80 such that the flow rate of the processing liquid L in the circulation line 72 may be equal to or less than the maximum flow rate of the processing liquid L during the circulation process.

Accordingly, during the shut-down process, it is possible to suppress the flow rate of flowing through the filter 76 from becoming larger than the flow rate of flowing during the most recent circulation process. Thus, foreign matter trapped in the filter 76 may be further suppressed from passing through the filter 76.

Therefore, according to the first modification, contamination of the processing liquid L in the circulation line 72 may be further suppressed.

Also, in the example of FIG. 7, descriptions have been made on an example in which in the shut-down process, the flow rate of the processing liquid L in the circulation line 72 is controlled to be equal to or less than the flow rate F1 in the circulation process, but the present disclosure is not limited to such an example.

For example, in the present disclosure, in the shut-down process, the pump 73 and the back pressure valve 80 may be controlled such that the flow rate of the processing liquid L in the circulation line 72 may be equal to or less than a flow rate slightly higher than the flow rate F1 in the circulation process.

This also makes it possible to suppress the flowing of the processing liquid L at a large flow rate through the filter 76 during the shut-down process. Thus, foreign matter trapped in the filter 76 may be suppressed from passing through the filter 76. Therefore, according to the first modification, contamination of the processing liquid L in the circulation line 72 may be suppressed.

FIG. 7 will be continuously described. As described above, the control unit 18 controls the flow rate of the processing liquid L in the circulation line 72 to be equal to or less than the flow rate F1 by lowering the discharge pressure of the pump 73 and increasing the valve opening degree of the back pressure valve 80.

Then, when the valve opening degree of the back pressure valve 80 is fully opened, and the flow rate of the processing liquid L in the circulation line 72 is equal to or less than the flow rate F1 (time T22), the control unit 18 assumes that the flow rate of the processing liquid L in the circulation line 72 is equal to or less than the flow rate F1, and turns OFF the control of the back pressure valve 80.

Then, when the control unit 18 shuts down the pump 73 after turning OFF the control of the back pressure valve 80, the discharge pressure of the pump 73 decreases. At time T23, the discharge pressure becomes zero. Next, the user performs a maintenance process for, for example, the processing liquid supply source 70.

Then, after this maintenance process is ended, in order to start up the circulation flow of the processing liquid L in the circulation line 72, the control unit 18 starts up the pump 73 at time T24 and turns ON the control of the back pressure valve 80 (a start-up process).

Here, in the first modification, in order to prevent an excessive increase in the flow rate of the processing liquid L in the circulation line 72 until the back pressure valve 80 is sufficiently operated, the control unit 18 operates the pump 73 such that the discharge pressure of the pump 73 may gradually increase.

Accordingly, as illustrated in FIG. 7, it is possible to suppress the flowing of the processing liquid at a large flow rate through the filter 76 during the start-up process. Thus, foreign matter trapped in the filter 76 may be suppressed from passing through the filter 76.

Therefore, according to the first modification, contamination of the processing liquid L in the circulation line 72 may be suppressed.

Also, in the first modification, in the start-up process, the pump 73 and the back pressure valve 80 may be controlled such that the flow rate of the processing liquid L in the circulation line 72 may be equal to or less than the maximum flow rate of the processing liquid L in the above-described previous circulation process.

Accordingly, in the start-up process, it is possible to suppress the flow rate of flowing through the filter 76 from becoming larger than the flow rate of flowing in the most recent circulation process. Thus, foreign matter trapped in the filter 76 may be further suppressed from passing through the filter 76.

Therefore, according to the first modification, contamination of the processing liquid L in the circulation line 72 may be further suppressed. Also, in the first modification, the circulation process is started again from time T25 when the control of the back pressure valve 80 is fully operated.

### Second Modification

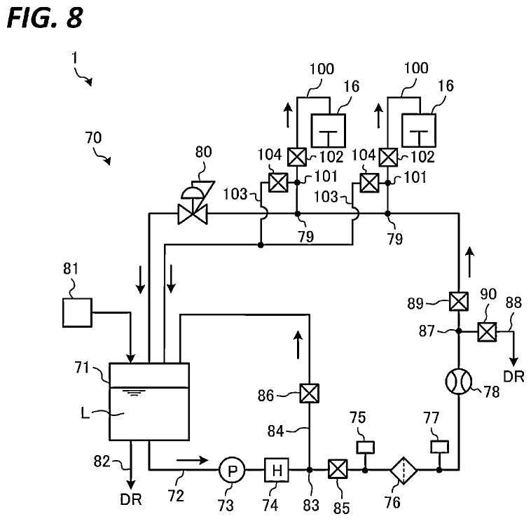

FIG. 8 is a view illustrating a schematic configuration of the processing liquid supply source 70 according to a second modification of the embodiment. As illustrated in FIG. 8, in the second modification, in the circulation line 72, the pump 73, the heater 74, a junction 83, a valve 85, the first pressure sensor 75, the filter 76, and the second pressure sensor 77 are provided in this order from the upstream side with respect to the tank 71. Furthermore, in this circulation line 72, the flowmeter 78, a junction 87, a valve 89, the plurality of junctions 79, and the back pressure valve 80 are provided in this order from the upstream side with respect to the second pressure sensor 77.

A branch circulation line 84 connected to the tank 71 diverges from the junction 83. In this branch circulation line 84, a valve 86 is provided. A drain line 88 connected to a drain section DR diverges from the junction 87. A valve 90 is provided in this drain line 88.

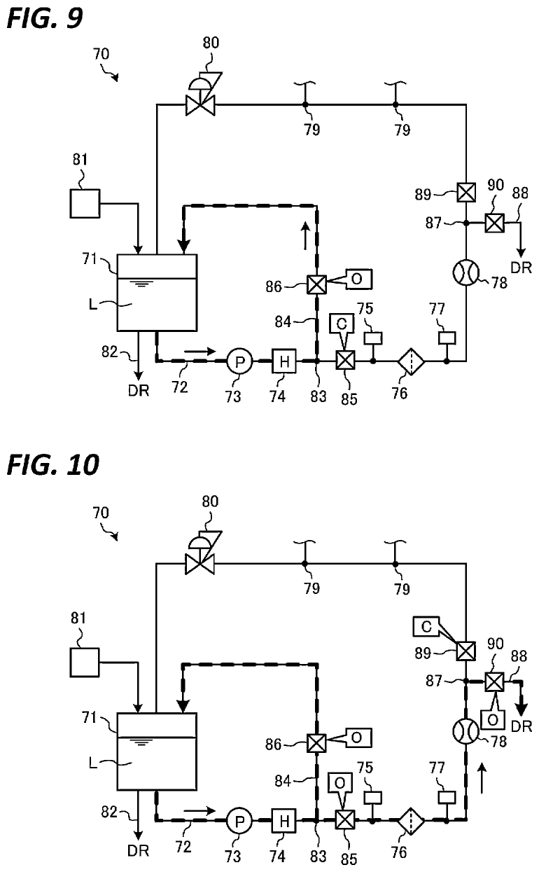

Next, details of a start-up process according to the second modification will be described with reference to FIG. 9 to FIG. 11. FIG. 9 to FIG. 11 are views illustrating the procedure of the start-up process in the processing liquid supply source 70 according to the second modification of the embodiment. Also, in FIG. 9 to FIG. 11, the processing units 16, etc. are omitted in the illustration.

As illustrated in FIG. 9, in the start-up process according to the second modification, first, the control unit 18 (see FIG. 1) operates the pump 73 and the heater 74, closes the valve 85, and opens the valve 86. Also, in the following drawings, “O” is given to the valve in an open state, and “C” is given to the valve in a close state.

Accordingly, as indicated by the bold dashed line in FIG. 9, in the processing liquid supply source 70, the circulation flow of the processing liquid L is formed through the circulation line 72 and the branch circulation line 84. Then, by operating the heater 74, and maintaining the circulation flow of the bold dashed line, the temperature of the processing liquid L in the tank 71 may be raised to a desired temperature.

Here, in the second modification, the circulation flow of the processing liquid L is formed through the circulation line 72 and the branch circulation line 84 while the temperature of the processing liquid L is raised. Thus, in the start-up process, the processing liquid L may be subjected to a temperature rise treatment without flowing through the filter 76.

Therefore, according to the second modification, it is possible to prevent contamination caused by particles passing through the filter 76 according to the temperature rise of the processing liquid L. Also, in the second modification, since the processing liquid L does not flow through the filter 76 where particles are trapped, contamination of the processing liquid L may be suppressed during the temperature rise treatment. Furthermore, in the second modification, since the pressure loss in the filter 76 may be avoided during the temperature rise treatment, the temperature of the processing liquid L may be efficiently raised.

Then, when the temperature of the processing liquid L in the tank 71 has reached a predetermined temperature, as illustrated in FIG. 10, the control unit 18 (see FIG. 1) maintains the operation of the pump 73 and the heater 74, opens the valves 85, 86, and 90, and closes the valve 89.

Accordingly, as indicated by the bold dashed line in FIG. 10, the circulation flow of the processing liquid L is continuously formed through the circulation line 72 and the branch circulation line 84, and the processing liquid L being heated is discharged to the drain section DR through the drain line 88.

Accordingly, when the processing liquid L being heated flows through the filter 76, even when the meshes of the filter 76 become coarse due to the temperature rise and particles trapped in the filter 76 pass through the filter 76, these particles may be suppressed from returning to the tank 71.

Therefore, according to the second modification, the processing liquid L containing a lot of particles that have passed through the filter 76 may be suppressed from diffusing into the circulation line 72 and returning to the tank 71.

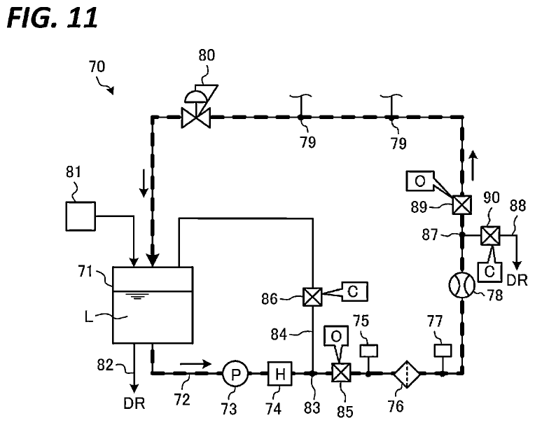

Then, the amount of the liquid discharged from the drain line 88, which is obtained on the basis of the measurement value of the flowmeter 78, reaches a predetermined amount, and then the particles passing through the filter 76 are reduced. Then, as illustrated in FIG. 11, the control unit 18 (see FIG. 1) maintains the operation of the pump 73 and the heater 74, opens the valves 85 and 89, and closes the valves 86 and 90.

Accordingly, as indicated by the bold dashed line in FIG. 11, in the processing liquid supply source 70, the circulation flow of the processing liquid L is formed through the circulation line 72. Also, before the step illustrated in FIG. 11, the control of the back pressure valve 80 is already turned ON.

Then, in the second modification, the contamination of the processing liquid L in the circulation line 72 may be suppressed by performing the control process in the start-up process similar to that in the above-described embodiment.

Also, in the second modification, after the temperature rise treatment of the processing liquid L is completed, the high-temperature processing liquid L is allowed to flow through the filter 76 so that the temperature of the filter 76 may be suppressed from returning to room temperature. As a result, the temperature of the filter 76, which has been returned to room temperature, is gradually raised to a predetermined high temperature due to the temperature rise treatment, and then it is possible to suppress meshes of the filter 76 from becoming coarse and a lot of particles from passing through the filter 76.

Therefore, according to the second modification, contamination of the processing liquid L in the circulation line 72 may be suppressed.

Also, in the second modification, the drain line 88 may be connected to the circulation line 72 on the downstream side of the filter 76 (here, the junction 87) rather than being directly connected to the filter 76.

When the drain line 88 is directly connected to the filter 76, it is very difficult to allow all of the processing liquid L that has flowed through the inside of the filter 76 to flow through the drain line 88. Meanwhile, in the second modification, since the drain line 88 is connected to the circulation line 72 on the downstream side of the filter 76, it is possible to allow all of the processing liquid L that has flowed through the inside of the filter 76 to flow through the drain line 88.

Therefore, according to the second modification, contamination of the processing liquid L in the circulation line 72 may be further suppressed.

Also, in the second modification, the flowmeter 78 may be located between the filter 76 and the drain line 88 (i.e., the junction 87) in the circulation line 72. Accordingly, in the process of discharging the processing liquid L to the drain section DR via the drain line 88 as illustrated in FIG. 10, the control unit 18 may accurately monitor the drainage amount of the processing liquid L being drained, on the basis of the value of the flowmeter 78.

Therefore, according to the second modification, in the process of discharging the processing liquid L to the drain section DR via the drain line 88, since excessive discharge of the processing liquid L may be suppressed, it is possible to reduce the wasteful disposal of the processing liquid L.

Also, in the above second modification, as illustrated in FIG. 10, an example has been described in which the circulation flow of the processing liquid L is formed through the circulation line 72 and the branch circulation line 84, and the processing liquid L being heated is discharged to the drain section DR via the drain line 88. However, the present disclosure is not limited to this example.

For example, after the processing illustrated in FIG. 9, the control unit 18 maintains the operation of the pump 73 and the heater 74, opens the valves 85 and 90, and closes the valves 86 and 89. Accordingly, the control unit 18 may discharge the processing liquid L for which the temperature rise treatment has been completed to the drain section DR via the drain line 88.

Accordingly, when the heated processing liquid L flows through the filter 76, even when the meshes of the filter 76 become coarse due to the temperature rise and particles trapped in the filter 76 pass through the filter 76, these particles may be suppressed from returning to the tank 71.

Also, in this case, after the processing liquid L for which the temperature rise treatment has been completed is discharged to the drain section DR via the drain line 88 for a predetermined time, the process may proceed to the processing illustrated in FIG. 11.

Also, in the above second modification, an example has been described in which after the processing liquid L being heated is discharged to the drain section DR via the drain line 88 as illustrated in FIG. 10, the circulation flow of the processing liquid L is formed through the circulation line 72 as illustrated in FIG. 11. However, the present disclosure is not limited to such an example.

For example, after the processing illustrated in FIG. 10, the control unit 18 may repeat the processing illustrated in FIG. 9 and the processing illustrated in FIG. 10 a plurality of times.

Accordingly, after the flow rate of the processing liquid L flowing through the filter 76 is returned to zero in the processing illustrated in FIG. 9, the processing liquid L can be allowed to flow through the filter 76 again in the processing illustrated in FIG. 10. This allows more particles trapped in the filter 76 to flow to the downstream side.

Therefore, according to the second modification, contamination of the processing liquid L in the circulation line 72 may be further suppressed.

Also, in the above second modification, an example has been described in which a process of discharging the processing liquid L through the drain line 88 is performed after the temperature of the processing liquid L is raised to a desired temperature while the processing liquid L is circulated through the branch circulation line 84. However, the present disclosure is not limited to such an example.

For example, in the present disclosure, the temperature of the processing liquid L may not be raised to a desired temperature through circulation of the processing liquid L in the branch circulation line 84. First, the processing liquid L corresponding to a predetermined drainage amount may be drained through the drain line 88, and then the processing liquid L may be circulated through the circulation line 72. This also makes it possible to suppress contamination of the processing liquid L in the circulation line 72.

### Third Modification

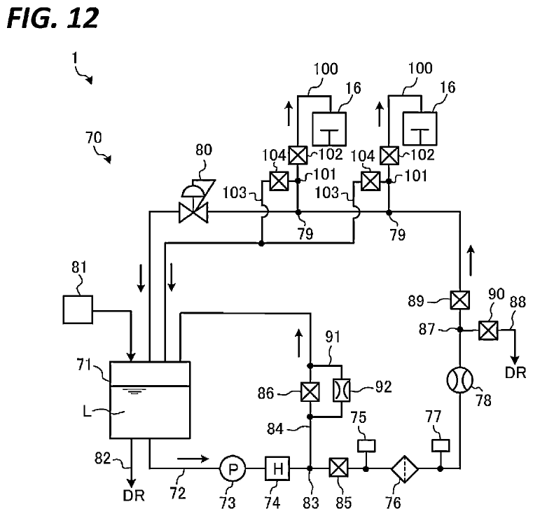

FIG. 12 is a view illustrating a schematic configuration of the processing liquid supply source 70 according to a third modification of the embodiment. As illustrated in FIG. 12, in the third modification, the configuration of the branch circulation line 84 is different from that in the above-described second modification.

Specifically, in the third modification, the branch circulation line 84 has a bypass line 91. This bypass line 91 is connected between the upstream side of the valve 86 and the downstream side of the valve 86 in the branch circulation line 84.

Also, an orifice 92 is formed in the bypass line 91. This orifice 92 reduces the flow rate of the processing liquid L flowing through the bypass line 91. The bypass line 91 and the orifice 92 are an example of a flow rate adjustment mechanism.

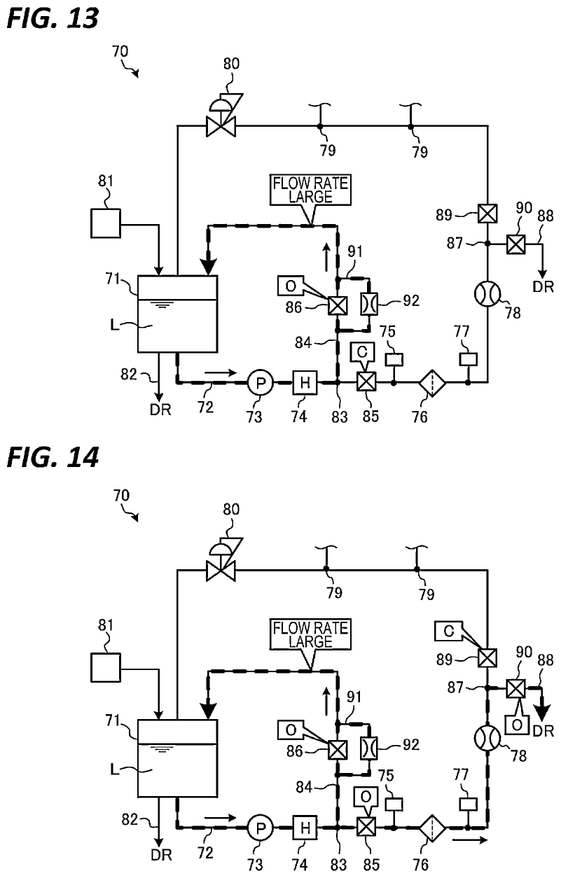

Next, details of a start-up process according to the third modification will be described with reference to FIG. 13 to FIG. 15. FIG. 13 to FIG. 15 are views illustrating the procedure of the start-up process in the processing liquid supply source 70 according to the third modification of the embodiment. Also, in FIG. 13 to FIG. 15, the processing units 16, etc. are omitted in the illustration.

As illustrated in FIG. 13, in the start-up process according to the third modification, first, the control unit 18 (see FIG. 1) operates the pump 73 and the heater 74, closes the valve 85, and opens the valve 86.

Accordingly, as indicated by the bold dashed line in FIG. 13, in the processing liquid supply source 70, the circulation flow of the processing liquid L is formed through the circulation line 72 and the branch circulation line 84. Also, in the process illustrated in FIG. 13, since the processing liquid L flows through both the branch circulation line 84 and the bypass line 91, the flow rate of the processing liquid L in the branch circulation line 84 is large.

Then, by operating the heater 74, and maintaining the circulation flow of the bold dashed line, the temperature of the processing liquid L in the tank 71 may be raised to a desired temperature.

Here, in the third modification, the circulation flow of the processing liquid L is formed through the circulation line 72 and the branch circulation line 84 while the temperature of the processing liquid L is raised. Thus, in the start-up process, the processing liquid L may be subjected to a temperature rise treatment without flowing through the filter 76.

Therefore, according to the third modification, it is possible to prevent contamination caused by particles passing through the filter 76 according to the temperature rise of the processing liquid L. Also, in the third modification, since the processing liquid L does not flow through the filter 76 where particles are trapped, contamination of the processing liquid L may be suppressed during the temperature rise treatment. Furthermore, in the third modification, since the pressure loss in the filter 76 may be avoided during the temperature rise treatment, the temperature of the processing liquid L may be efficiently raised.

Then, when the temperature of the processing liquid L in the tank 71 has reached a predetermined temperature, as illustrated in FIG. 14, the control unit 18 (see FIG. 1) maintains the operation of the pump 73 and the heater 74, opens the valves 85, 86, and 90, and closes the valve 89.

Accordingly, as indicated by the bold dashed line in FIG. 14, the circulation flow of the processing liquid L is continuously formed through the circulation line 72 and the branch circulation line 84, and the processing liquid L being heated is discharged to the drain section DR through the drain line 88. Also, in the process illustrated in FIG. 14, since the processing liquid L flows through both the branch circulation line 84 and the bypass line 91, the flow rate of the processing liquid L in the branch circulation line 84 is large.

Accordingly, when the processing liquid L being heated flows through the filter 76, even when the meshes of the filter 76 become coarse due to the temperature rise and particles trapped in the filter 76 pass through the filter 76, these particles may be suppressed from returning to the tank 71.

Therefore, according to the third modification, the processing liquid L containing a lot of particles that have passed through the filter 76 may be suppressed from diffusing into the circulation line 72 and returning to the tank 71.

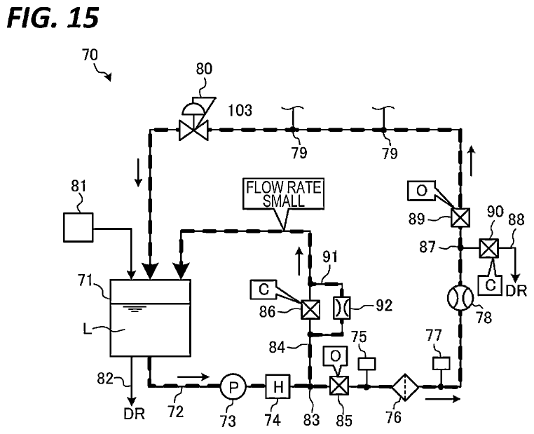

Then, when the particles passing through the filter 76 are reduced as a predetermined time has passed, as illustrated in FIG. 15, the control unit 18 (see FIG. 1) maintains the operation of the pump 73 and the heater 74, opens the valves 85 and 89, and closes the valves 86 and 90.

Accordingly, as indicated by the bold dashed line in FIG. 15, in the processing liquid supply source 70, the circulation flow of the processing liquid L is formed through the circulation line 72, and the circulation flow of the processing liquid L is continuously formed through the circulation line 72 and the branch circulation line 84.

Also, before the step illustrated in FIG. 15, the control of the back pressure valve 80 is already turned ON. Also, in the process illustrated in FIG. 15, since the processing liquid L flows through only the bypass line 91 in the branch circulation line 84, the flow rate of the processing liquid L in the branch circulation line 84 is small.

Then, in the third modification, the contamination of the processing liquid L in the circulation line 72 may be suppressed by performing the control process in the start-up process similar to that in the above-described embodiment.

Also, in the third modification, after the temperature rise treatment of the processing liquid L is completed, the high-temperature processing liquid L is allowed to flow through the filter 76 so that the temperature of the filter 76 may be suppressed from returning to room temperature. As a result, the temperature of the filter 76, which has been returned to room temperature, is gradually raised to a predetermined high temperature due to the temperature rise treatment, and then it is possible to suppress meshes of the filter 76 from becoming coarse and a lot of particles from passing through the filter 76.

Therefore, according to the third modification, contamination of the processing liquid L in the circulation line 72 may be suppressed.

Also, in the third modification, unlike in the above-described second modification, as illustrated in FIG. 15, during the circulation process of the processing liquid L in the circulation line 72, a circulation flow with a small flow rate is also formed in the branch circulation line 84. This makes it possible to suppress retention of the processing liquid L in the branch circulation line 84 during circulation of the processing liquid L in the circulation line 72.

That is, in the third modification, after the maintenance process for, for example, the processing liquid supply source 70 is performed again, when the start-up process of the circulation flow is performed again, the processing liquid L may be prevented from being contaminated by particles, etc. by using the branch circulation line 84 in which the processing liquid L has been retained.

Therefore, according to the third modification, contamination of the processing liquid L in the circulation line 72 may be suppressed.

Also, in the third modification, as illustrated in FIG. 15, in circulating the processing liquid L in the circulation line 72, the processing liquid L may be allowed to circulate through the branch circulation line 84 at a flow rate smaller than before the circulation of the processing liquid L in the circulation line 72 is started.

Accordingly, it is possible to maintain both the circulation flow in the circulation line 72 and the circulation flow in the branch circulation line 84 without excessively increasing the rated flow rate of the pump 73. Therefore, according to the third modification, the production cost of the processing liquid supply source 70 may be reduced.

Also, in the example of FIG. 12 to FIG. 15, an example has been described in which the bypass line 91 and the orifice 92 are used as a flow rate adjustment mechanism of the branch circulation line 84. However, the present disclosure is not limited to such an example.

For example, a valve capable of controlling two or more types of valve opening degrees may be provided in the branch circulation line 84, and the control unit 18 may control the valve opening degree of the valve, thereby adjusting the flow rate of the processing liquid L in the branch circulation line 84.

This also makes it possible to prevent the processing liquid L from being contaminated by particles, etc. by using the branch circulation line 84 where the processing liquid L is retained when the start-up process of the circulation flow is performed again. Thus, the contamination of the processing liquid L in the circulation line 72 may be suppressed.

### Fourth Modification

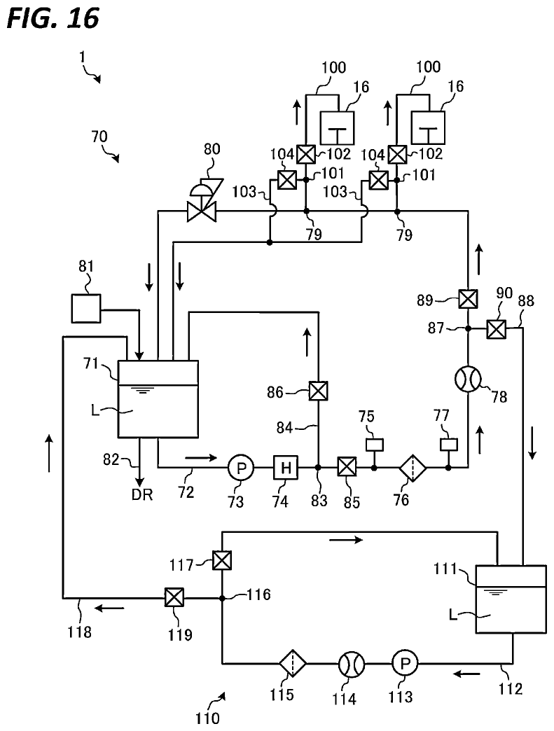

FIG. 16 is a view illustrating a schematic configuration of the processing liquid supply source 70 according to a fourth modification of the embodiment. As illustrated in FIG. 16, in this fourth modification, the downstream side configuration of the drain line 88 is different from that in the above-described second modification.

Specifically, in the fourth modification, the drain line 88 is connected to a recovery mechanism 110 instead of the drain section DR (see FIG. 8). This recovery mechanism 110 includes a recovery tank 111, a circulation line 112, a pump 113, a flowmeter 114, a filter 115, a junction 116, and a valve 117. The filter 115 is an example of a filtering mechanism.

The recovery tank 111 collects and stores the processing liquid L discharged from the drain line 88. The circulation line 112 returns the processing liquid L sent from the recovery tank 111, to the recovery tank 111. In the circulation line 112, the pump 113, the flowmeter 114, the filter 115, the junction 116, and the valve 117 are provided in this order from the upstream side with respect to the recovery tank 111.

The pump 113 forms the circulation flow of the processing liquid L in the circulation line 112. The flowmeter 114 measures the flow rate of the circulation flow of the processing liquid L formed in the circulation line 112. The filter 115 removes contaminants such as particles contained in the processing liquid L circulating through the inside of the circulation line 112.

A return line 118 connected to the tank 71 diverges from the junction 116. A valve 119 is provided in the return line 118.

Here, in the fourth modification, the processing liquid L discharged from the drain line 88 is collected by the recovery mechanism 110, and the processing liquid L is filtered by this recovery mechanism.

Specifically, the control unit 18 (see FIG. 1) forms the circulation flow of the processing liquid L in the circulation line 112 by operating the pump 113, and allows the circulating processing liquid L to repeatedly flow through the filter 115 so that the processing liquid L is filtered. Here, the control unit 18 opens the valve 117, and closes the valve 119.

Then, when the processing liquid L in the recovery tank 111 has reached a predetermined cleanliness, the control unit 18 closes the valve 117, and opens the valve 119. Accordingly, the control unit 18 returns the cleanly filtered processing liquid L from the recovery tank 111 to the tank 71 via the circulation line 112 and the return line 118.

Accordingly, the amount of the processing liquid L to be discarded in the drain section DR may be reduced. Therefore, according to the fourth modification, the use amount of the processing liquid L may be reduced, so that the processing cost of the wafer W may be reduced.

Also, in the fourth modification, the temperature of the processing liquid L circulating through the circulation line 112 may be lower than the temperature of the processing liquid L circulating through the circulation line 72. For example, the temperature of the processing liquid L circulating through the circulation line 112 may be room temperature.

Accordingly, more particles may be aggregated within the processing liquid L circulating through the circulation line 112. Therefore, according to the fourth modification, the processing liquid L may be efficiently filtered in the recovery mechanism 110.

The liquid supply system according to the embodiment (the processing liquid supply source 70) includes the tank 71, the circulation line 72, the pump 73, the filter 76, the back pressure valve 80, and the control unit 18. The tank 71 stores the processing liquid L. The circulation line 72 returns the processing liquid L sent from the tank 71, to the tank 71. The pump 73 forms the circulation flow of the processing liquid L in the circulation line 72. The filter 76 is provided on the downstream side of the pump 73 in the circulation line 72. The back pressure valve 80 is provided on the downstream side of the filter 76 in the circulation line 72. The control unit 18 controls each unit. Also, when stopping the operation of the pump 73, the control unit 18 controls the pump 73 and the back pressure valve 80 such that the differential pressure between the upstream side and the downstream side of the filter 76 may be equal to or less than a predetermined threshold value, during a period from when the discharge pressure of the pump 73 starts to decrease until the operation of the pump 73 is stopped. Accordingly, contamination of the processing liquid L in the circulation line 72 may be suppressed.

Also, in the liquid supply system according to the embodiment (the processing liquid supply source 70), the control unit 18 controls the differential pressure between the upstream side and the downstream side of the filter 76 to be equal to or less than the predetermined threshold value by lowering the discharge pressure of the pump 73 and increasing the valve opening degree of the back pressure valve 80. This makes it possible to further suppress the contamination of the processing liquid L in the circulation line 72.

Also, in the liquid supply system according to the embodiment (the processing liquid supply source 70), when stopping the operation of the pump 73, the control unit 18 controls the pump 73 and the back pressure valve 80 such that the differential pressure between the upstream side and the downstream side of the filter 76 may be equal to or less than a maximum differential pressure. Such a maximum differential pressure is the maximum differential pressure between the upstream side and the downstream side of the filter 76 when the circulation flow of the processing liquid L is formed in the circulation line 72. Accordingly, contamination of the processing liquid L in the circulation line 72 may be further suppressed.

Also, the liquid supply system according to the embodiment (the processing liquid supply source 70) further includes the first pressure sensor 75 provided on the upstream side of the filter 76, and the second pressure sensor 77 provided on the downstream side of the filter 76. Also, the control unit 18 calculates the maximum differential pressure between the first pressure sensor 75 and the second pressure sensor 77 when the circulation flow of the processing liquid L is formed in the circulation line 72. Furthermore, when stopping the operation of the pump 73, the control unit 18 controls the pump 73 and the back pressure valve 80 such that the differential pressure between the upstream side and the downstream side of the filter 76 may be equal to or less than such a maximum differential pressure. This makes it possible to further suppress the contamination of the processing liquid L in the circulation line 72.

Also, in the liquid supply system according to the embodiment (the processing liquid supply source 70), when starting the circulation of the processing liquid L in the circulation line 72, the control unit 18 controls the pump 73 and the back pressure valve 80 such that the differential pressure between the upstream side and the downstream side of the filter 76 may be equal to or less than the maximum differential pressure. Such a maximum differential pressure is the maximum differential pressure between the upstream side and the downstream side of the filter 76 when the circulation flow of the processing liquid L is formed in the circulation line 72. Accordingly, contamination of the processing liquid L in the circulation line 72 may be further suppressed.

Also, the liquid supply system according to the embodiment (the processing liquid supply source 70) further includes a heating mechanism (the heater 74) and the branch circulation line 84. The heating mechanism (the heater 74) is provided between the pump 73 and the filter 76 in the circulation line 72. The branch circulation line 84 branches off between the heating mechanism (the heater 74) and the filter 76 in the circulation line 72, and returns the processing liquid L sent from the tank 71, to the tank 71. Also, before starting the circulation of the processing liquid L in the circulation line 72, the control unit 18 heats the processing liquid L with the heating mechanism (the heater 74) while operating the pump 73 to circulate the processing liquid L through the branch circulation line 84. This makes it possible to suppress contamination of the processing liquid L during the temperature rise treatment.

Also, the liquid supply system according to the embodiment (the processing liquid supply source 70) further includes the junctions 79, the valve 89, and the drain line 88. The junction 79 is on the downstream side of the filter 76 in the circulation line 72, and the supply line 100 for supplying the processing liquid L to the substrate processing section 30 diverges from the junction 79. The valve 89 is provided between the filter 76 and the junction 79. The drain line 88 is connected between the filter 76 and the valve 89 in the circulation line 72. Also, before starting circulation through the circulation line 72, the control unit 18 closes the valve 89 so that the processing liquid L is circulated through the branch circulation line 84 and is heated by the heating mechanism (the heater 74). Then, after being heated by the heating mechanism (the heater 74), the processing liquid L is discharged from the drain line 88. Accordingly, the processing liquid L containing a lot of particles that have passed through the filter 76 may be suppressed from diffusing into the circulation line 72 and returning to the tank 71.

Also, in the liquid supply system according to the embodiment (the processing liquid supply source 70), before starting circulation of the processing liquid L in the circulation line 72, the control unit 18 repeats circulation in the branch circulation line 84 and discharging of liquid from the drain line 88. Accordingly, contamination of the processing liquid L in the circulation line 72 may be further suppressed.

Also, the liquid supply system according to the embodiment (the processing liquid supply source 70) further includes the flowmeter 78 provided between the filter 76 and the valve 89. Also, the drain line 88 is connected to the downstream side of the flowmeter 78 in the circulation line 72. Also, the control unit 18 monitors the drainage amount of the processing liquid L drained from the drain line 88, by the flowmeter 78. This makes it possible to reduce the wasteful disposal of the processing liquid L.

Also, in the liquid supply system according to the embodiment (the processing liquid supply source 70), when the drainage amount has reached a predetermined amount, the control unit 18 opens the valve 90 to allow the processing liquid L to flow through the circulation line 72, thereby forming the circulation flow. Accordingly, the wasteful disposal of the processing liquid L may be reduced.

Also, in the liquid supply system according to the embodiment (the processing liquid supply source 70), the control unit 18 circulates the processing liquid L in the branch circulation line 84 while circulating the processing liquid L in the circulation line 72. This makes it possible to suppress the contamination of the processing liquid L in the circulation line 72.

Also, the liquid supply system according to the embodiment (the processing liquid supply source 70) further includes a flow rate adjustment mechanism (the bypass line 91 and the orifice 92) that is provided in the branch circulation line 84, and adjusts the flow rate of the processing liquid L flowing through the branch circulation line 84. Also, when the processing liquid L is circulated through the circulation line 72, the control unit 18 circulates the processing liquid L through the branch circulation line 84 at a flow rate smaller than before the circulation of the processing liquid L in the circulation line 72 is started. Accordingly, the production cost of the processing liquid supply source 70 may be reduced.

Also, the liquid supply system according to the embodiment (the processing liquid supply source 70) further includes the recovery tank 111, a filtering mechanism (the filter 115), and the return line 118. The recovery tank 111 collects the processing liquid L flowing through the drain line 88. The filtering mechanism (the filter 115) filters the processing liquid L collected in the recovery tank 111. The return line 118 connects the filtering mechanism (the filter 115) and the tank 71 to each other, and returns the processing liquid L filtered by the filtering mechanism (the filter 115), to the tank 71. Accordingly, the processing cost of the wafer W may be reduced.

Also, the liquid supply system according to the embodiment (the processing liquid supply source 70) further includes the junctions 79, the valve 89, and the drain line 88. The junction 79 is on the downstream side of the filter 76 in the circulation line 72, and the supply line 100 for supplying the processing liquid L to the substrate processing section 30 diverges from the junction 79. The valve 89 is provided between the filter 76 and the junction 79. The drain line 88 is connected between the filter 76 and the valve 89 in the circulation line 72. Also, before starting circulation of the processing liquid L in the circulation line 72, the control unit 18 closes the valve 89 and drains the processing liquid L from the drain line 88. Accordingly, the processing liquid L containing a lot of particles that have passed through the filter 76 may be suppressed from diffusing into the circulation line 72 and returning to the tank 71.

Also, the liquid supply system according to the embodiment (the processing liquid supply source 70) includes the tank 71, the circulation line 72, the pump 73, the filter 76, the back pressure valve 80, and the control unit 18. The tank 71 stores the processing liquid L. The circulation line 72 returns the processing liquid L sent from the tank 71, to the tank 71. The pump 73 forms the circulation flow of the processing liquid L in the circulation line 72. The filter 76 is provided on the downstream side of the pump 73 in the circulation line 72. The back pressure valve 80 is provided on the downstream side of the filter 76 in the circulation line 72. The control unit 18 controls each unit. Also, when stopping the operation of the pump 73, the control unit 18 controls the pump 73 and the back pressure valve 80 such that the flow rate of the processing liquid L flowing through the circulation line 72 may be equal to or less than a predetermined threshold value, during a period from when the discharge pressure of the pump 73 starts to decrease until the operation of the pump 73 is stopped. Accordingly, contamination of the processing liquid L in the circulation line 72 may be suppressed.

Also, the liquid processing apparatus (the substrate processing system 1) according to the embodiment includes the liquid processing units (the processing units 16) and the supply lines 100. The liquid processing unit (the processing unit 16) processes the substrate (wafer W) with the processing liquid L. The supply line 100 supplies the processing liquid L from the above-described liquid supply system (the processing liquid supply source 70) to the liquid processing unit (the processing unit 16). Accordingly, it is possible to process the wafer W with the processing liquid L whose contamination is suppressed in the processing liquid supply source 70.

### <Procedure of Control Process>

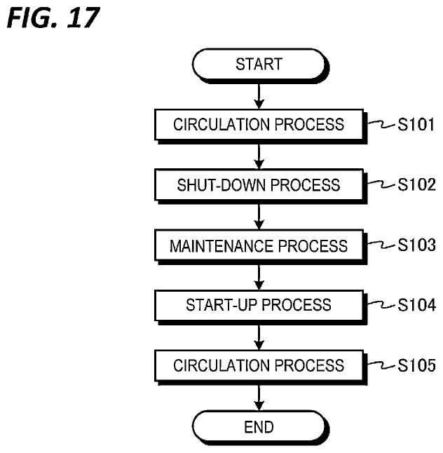

Next, the procedure of the control process according to the embodiment will be described with reference to FIG. 17. FIG. 17 is a flowchart illustrating an example of the procedure of the control process executed by the substrate processing system 1 according to the embodiment.

In the control process according to the embodiment, the control unit 18 circulates the processing liquid L through the circulation line 72 by operating the pump 73 and the heater 74 (step S101). Also, in this processing of step S101, the control unit 18 obtains the maximum differential pressure between the upstream side and the downstream side of the filter 76 by operating the first pressure sensor 75 and the second pressure sensor 77.

Also, in the processing of step S101, the control unit 18 may obtain the maximum flow rate of the processing liquid L in the circulation line 72 by operating the flowmeter 78.

Next, the control unit 18 shuts down the circulation flow of the processing liquid L in the circulation line 72 (step S102). Here, the control unit 18 controls the pump 73 and the back pressure valve 80 such that the differential pressure between the upstream side and the downstream side of the filter 76 may be equal to or less than a predetermined threshold value (for example, the maximum differential pressure between the upstream side and the downstream side of the filter 76 in the processing of step S101).

Also, in the processing of step S102, the control unit 18 may control the pump 73 and the back pressure valve 80 such that the flow rate of the processing liquid L in the circulation line 72 may be equal to or less than a predetermined threshold value (for example, the maximum flow rate of the processing liquid L in the processing of step S101).

Next, a maintenance process, such as cleaning the inside of the tank 71, replacement of the processing liquid L, and recovery from any trouble, is performed (step S103). Then, the control unit 18 starts up the circulation flow of the processing liquid L in the circulation line 72 (step S104).

Here, the control unit 18 operates the pump 73 such that the discharge pressure of the pump 73 may gradually increase. Also, in this processing of step S104, the control unit 18 may control the pump 73 and the back pressure valve 80 such that the differential pressure between the upstream side and the downstream side of the filter 76 may be equal to or less than the maximum differential pressure between the first pressure sensor 75 and the second pressure sensor 77 in the above-described circulation process.

Furthermore, in this processing of step S104, the control unit 18 may control the pump 73 and the back pressure valve 80 such that the flow rate of the processing liquid L in the circulation line 72 may be equal to or less than the maximum flow rate of the processing liquid L in the above-described circulation process.

Then, when the control of the back pressure valve 80 is fully operated, the process returns to the circulation process of the processing liquid L again (step S105), and the series of control processes ends.

The liquid supply method according to the embodiment includes a process (step S101) of forming a circulation flow, a process (step S102) of shutting down the circulation flow, and a process (step S104) of starting up the circulation flow. In the process (step S101) of forming the circulation flow, the pump 73 is operated to form the circulation flow of the processing liquid L in the circulation line 72 that returns the processing liquid L sent from the tank 71, to the tank 71. In the process (step S102) of shutting down the circulation flow, the circulation flow of the processing liquid L in the circulation line 72 is shut down. The process (step S104) of starting up the circulation flow starts up the circulation flow of the processing liquid L in the circulation line 72. In the process of shutting down the circulation flow, in stopping the operation of the pump 73, the pump 73 and the back pressure valve 80 are controlled such that the differential pressure between the upstream side and the downstream side of the filter 76 may be equal to or less than a predetermined threshold value, during a period from when the discharge pressure of the pump 73 starts to decrease until the operation of the pump 73 is stopped. The filter 76 is provided on the downstream side of the pump 73 in the circulation line 72. The back pressure valve 80 is provided on the downstream side of the filter 76 in the circulation line 72. Accordingly, the contamination of the processing liquid L in the circulation line 72 may be suppressed.

Also, in the liquid supply method according to the embodiment, in the process (step S102) of shutting down the circulation flow, in stopping the operation of the pump 73, the pump 73 and the back pressure valve 80 are controlled such that the differential pressure between the upstream side and the downstream side of the filter 76 may be equal to or less than the maximum differential pressure. Such a maximum differential pressure is the maximum differential pressure between the upstream side and the downstream side of the filter 76 during the circulation flow forming process (step S101). Accordingly, the contamination of the processing liquid L in the circulation line 72 may be suppressed.

Also, in the liquid supply method according to the embodiment, in the process of starting up the circulation flow (step S104), when the circulation of the processing liquid L in the circulation line 72 is started, the pump 73 and the back pressure valve 80 are controlled such that the differential pressure between the upstream side and the downstream side of the filter 76 may be equal to or less than the maximum differential pressure. Such a maximum differential pressure is the maximum differential pressure between the upstream side and the downstream side of the filter 76 during the circulation flow forming process (step S101). Accordingly, the contamination of the processing liquid L in the circulation line 72 may be suppressed.

So far, the embodiments of the present disclosure has been described, but the present disclosure is not limited to the above embodiments, and various modifications are possible without departing from the spirit of the disclosure.

The embodiments disclosed herein should be considered to be illustrative and not restrictive in all aspects. In fact, the above embodiments may be embodied in various forms. Also, the above embodiments may be omitted, replaced, or modified in various forms without departing from the scope and spirit of the appended claims.

### DESCRIPTION OF SYMBOLS

W: wafer, 1: substrate processing system (an example of a liquid processing apparatus), 16: processing unit (an example of a liquid processing unit), 18: control unit, 30: substrate processing section, 70: processing liquid supply source (an example of a liquid supply system), 71: tank, 72: circulation line, 73: pump, 74: heater (an example of a heating mechanism), 75: first pressure sensor, 76: filter, 77: second pressure sensor, 78: flowmeter, 79: junction, 80: back pressure valve, 84: branch circulation line, 88: drain line, 89: valve, 91: bypass line (an example of a flow rate adjustment mechanism), 92: orifice (an example of a flow rate adjustment mechanism), 100: supply line, 110: recovery mechanism, 111: recovery tank, 115: filter (an example of a filtering mechanism), 118: return line, L: processing liquid

1. A liquid supply system comprising:
a tank configured to store a processing liquid;
a circulation line configured to return the processing liquid sent from the tank, to the tank;
a pump configured to form a circulation flow of the processing liquid in the circulation line;
a primary filter provided on a downstream side of the pump in the circulation line;
a back pressure valve provided on a downstream side of the primary filter in the circulation line; and
a controller configured to control each unit,
wherein when stopping an operation of the pump, the controller controls the pump and the back pressure valve such that a differential pressure between an upstream side and a downstream side of the primary filter becomes equal to or less than a predetermined threshold value, during a period from when a discharge pressure of the pump starts to decrease until the operation of the pump is stopped.

2. The liquid supply system according to claim 1, wherein the controller controls the differential pressure between the upstream side and the downstream side of the filter to be equal to or less than the predetermined threshold value by lowering the discharge pressure of the pump and increasing a valve opening degree of the back pressure valve.

3. The liquid supply system according to claim 1, wherein when stopping the operation of the pump, the controller controls the pump and the back pressure valve such that the differential pressure between the upstream side and the downstream side of the primary filter becomes equal to or less than a maximum differential pressure between the upstream side and the downstream side of the filter when the circulation flow of the processing liquid is formed in the circulation line.

4. The liquid supply system according to claim 1, further comprising:
a first pressure sensor provided on the upstream side of the primary filter; and
a second pressure sensor provided on the downstream side of the primary filter,
wherein the controller calculates a maximum differential pressure between the first pressure sensor and the second pressure sensor when the circulation flow of the processing liquid is formed in the circulation line, and
when stopping the operation of the pump, the controller controls the pump and the back pressure valve such that the differential pressure between the upstream side and the downstream side of the primary filter becomes equal to or less than the maximum differential pressure.

5. The liquid supply system according to claim 1, wherein when starting circulation of the processing liquid in the circulation line, the controller controls the pump and the back pressure valve such that the differential pressure between the upstream side and the downstream side of the primary filter becomes equal to or less than a maximum differential pressure between the upstream side and the downstream side of the primary filter when the circulation flow of the processing liquid is formed in the circulation line.

6. The liquid supply system according to claim 1, further comprising:
a heater provided between the pump and the primary filter in the circulation line; and
a branch circulation line branching off between the heater and the primary filter in the circulation line, and returns the processing liquid sent from the tank, to the tank,
wherein before starting circulation of the processing liquid in the circulation line, the controller heats the processing liquid with the heater while operating the pump to circulate the processing liquid through the branch circulation line.

7. The liquid supply system according to claim 6, further comprising:
a junction on the downstream side of the primary filter in the circulation line, from which a supply line for supplying the processing liquid to a substrate processing section diverges;
a valve provided between the primary filter and the junction; and
a drain line connected between the primary filter and the valve in the circulation line,
wherein before starting the circulation of the processing liquid in the circulation line, the controller closes the valve and heats the processing liquid with the heater while circulating through the branch circulation line, and then drains the processing liquid from the drain line after heating with the heater.

8. The liquid supply system according to claim 7, wherein before starting the circulation of the processing liquid in the circulation line, the controller repeats circulating in the branch circulation line and draining from the drain line.

9. The liquid supply system according to claim 7, further comprising:
a flowmeter provided between the primary filter and the valve,
wherein the drain line is connected to a downstream side of the flowmeter in the circulation line, and
the controller monitors a drainage amount of the processing liquid drained from the drain line, by the flowmeter.

10. The liquid supply system according to claim 9, wherein when the drainage amount has reached a predetermined amount, the controller opens the valve to allow the processing liquid to flow through the circulation line, thereby forming the circulation flow.

11. The liquid supply system according to claim 6, wherein the controller circulates the processing liquid in the branch circulation line while circulating the processing liquid in the circulation line.

12. The liquid supply system according to claim 11, further comprising:
a flow rate adjustor provided in the branch circulation line, and configured to adjust a flow rate of the processing liquid flowing through the branch circulation line,
wherein when the processing liquid is circulated through the circulation line, the controller circulates the processing liquid through the branch circulation line at a flow rate smaller than before the circulation of the processing liquid in the circulation line is started.

13. The liquid supply system according to claim 7, further comprising:
a recovery tank configured to collect the processing liquid flowing through the drain line;
a recovery filter configured to filter the processing liquid collected in the recovery tank; and
a return line configured to connect the recovery filter and the tank to each other, and return the processing liquid filtered by the recovery filter to the tank.

14. The liquid supply system according to claim 1, further comprising:
a junction on the downstream side of the primary filter in the circulation line, from which a supply line for supplying the processing liquid to a substrate processing section diverges;
a valve provided between the primary filter and the junction; and
a drain line connected between the primary filter and the valve in the circulation line,
wherein before starting circulation of the processing liquid in the circulation line, the controller closes the valve and drains the processing liquid from the drain line.

15. A liquid supply system comprising:
a tank configured to store a processing liquid;
a circulation line configured to return the processing liquid sent from the tank, to the tank;
a pump configured to form a circulation flow of the processing liquid in the circulation line;
a filter provided on a downstream side of the pump in the circulation line;
a back pressure valve provided on a downstream side of the filter in the circulation line; and
a controller configured to control each unit,
wherein when stopping an operation of the pump, the controller controls the pump and the back pressure valve such that a flow rate of the processing liquid flowing through the circulation line becomes equal to or less than a predetermined threshold value, during a period from when a discharge pressure of the pump starts to decrease until the operation of the pump is stopped.

16. A liquid processing apparatus comprising:
a liquid processing section configured to process a substrate with the processing liquid; and
a supply line configured to supply the processing liquid to the liquid processing section from the liquid supply system according to claim 1.

17. A liquid supply method comprising:
operating a pump, thereby forming a circulation flow of a processing liquid in a circulation line that returns the processing liquid sent from a tank, to the tank;
shutting down the circulation flow of the processing liquid in the circulation line; and
starting up the circulation flow of the processing liquid in the circulation line,
wherein in the shutting down of the circulation flow, when stopping an operation of the pump, the pump and a back pressure valve are controlled such that a differential pressure between an upstream side and a downstream side of a filter becomes equal to or less than a predetermined threshold value, during a period from when a discharge pressure of the pump starts to decrease until the operation of the pump is stopped, the back pressure valve being provided on the downstream side of the filter in the circulation line, and the filter being provided on a downstream side of the pump in the circulation line.

18. The liquid supply method according to claim 17, wherein in the shutting down of the circulation flow, when stopping the operation of the pump, the pump and the back pressure valve are controlled such that the differential pressure between the upstream side and the downstream side of the filter becomes equal to or less than a maximum differential pressure between the upstream side and the downstream side of the filter during the forming of the circulation flow.

19. The liquid supply method according to claim 17, wherein in the starting up of the circulation flow, when circulation of the processing liquid in the circulation line is started, the pump and the back pressure valve are controlled such that the differential pressure between the upstream side and the downstream side of the filter becomes equal to or less than a maximum differential pressure between the upstream side and the downstream side of the filter during the forming of the circulation flow.
